(19) United States
(12) Patent Application Publication
(10) Pub. No.: US 2024/0413273 A1
(43) Pub. Date: Dec. 12, 2024

(54) DISPLAY DEVICE AND MANUFACTURING METHOD THEREOF

(71) Applicant: Samsung Display Co., LTD., Yongin-si (KR)

(72) Inventors: Tae Young SONG, Yongin-si (KR); Jin Won KIM, Yongin-si (KR); Hye-Jin PAEK, Yongin-si (KR)

(73) Assignee: Samsung Display Co., LTD., Yongin-si (KR)

(21) Appl. No.: 18/590,308

(22) Filed: Feb. 28, 2024

(30) Foreign Application Priority Data
Jun. 9, 2023 (KR) 10-2023-0074178

(51) Int. Cl. H01L 33/50; H01L 25/075; H01L 25/16; H01L 33/54

(52) U.S. Cl. CPC H01L 33/505; H01L 25/0753; H01L 25/167; H01L 33/54; H01L 2933/0041

(57) ABSTRACT

A display device includes a first substrate, a transistor disposed on the first substrate, a light emitting device connected to the transistor, an encapsulation layer covering the light emitting device, a plurality of banks disposed to overlap the encapsulation layer in a plan view and partitioning a first emission area, a second emission area, and a third emission area, a first color conversion layer disposed in the first emission area, a second color conversion layer disposed in the second emission area, and a transmission layer disposed in the third emission area. A thickness of at least one of the first color conversion layer or the second color conversion layer is greater than a thickness of the plurality of banks.

### CROSS-REFERENCE TO RELATED APPLICATION(S)

This application claims priority to and the benefit of Korean Patent Application No. 10-2023-0074178 under 35 U.S.C. § 119, filed on Jun. 9, 2023, in the Korean Intellectual Property Office (KIPO), the entire contents of which are incorporated herein by reference.

### BACKGROUND

### 1. Technical Field

The disclosure relates to a display device and a manufacturing method thereof.

### 2. Description of the Related Art

In a light emitting device, a hole supplied from an anode and an electron supplied from a cathode are combined in a light emitting layer formed between the anode and the cathode to form an exciton, and it is a device that emits light while the exciton is stabilized.

The light emitting device has several advantages such as a wide viewing angle, a fast response speed, a thin thickness, and low power consumption, and thus it is widely applied to various electric and electronic devices such as televisions, monitors, and mobile phones.

Recently, a display device including a color conversion panel has been proposed to implement a display device with high efficiency. The color conversion panel color-converts incident light into light having different colors, or transmits it. In this case, incident light is blue light, and the blue light is converted into red light and green light, or is transmitted as blue light itself.

### SUMMARY

Embodiments attempt to provide a display device with improved light emission efficiency and a manufacturing method therefor.

According to an embodiment of the disclosure, a display device may include a first substrate, a transistor disposed on the first substrate, a light emitting device connected to the transistor, an encapsulation layer covering the light emitting device, a plurality of banks disposed to overlap the encapsulation layer in a plan view and partitioning a first emission area, a second emission area, and a third emission area, a first color conversion layer disposed in the first emission area, a second color conversion layer positioned in the second emission area, and a transmission layer disposed in the third emission area. A thickness of at least one of the first color conversion layer and the second color conversion layer may be greater than a thickness of the plurality of banks.

A difference between the thickness of the at least one of the first color conversion layer and the second color conversion layer, and the thickness of the plurality of banks may be in a range of about 1 μm to about 5 μm.

An upper surface of the at least one of the first color conversion layer and the second color conversion layer, which is thicker than the thickness of the plurality of banks, may be flat.

An upper surface of the at least one of the first color conversion layer and the second color conversion layer, which is thicker than the thickness of the plurality of banks, may be curved.

A portion of the at least one of the first color conversion layer and the second color conversion layer, which is thicker than the thickness of the plurality of banks, may be positioned to overlap the banks in a plan view.

A side surface of the at least one of the first color conversion layer and the second color conversion layer, which is thicker than the thickness of the plurality of banks, may be spaced apart from the plurality of banks.

The display device may further include a cover layer disposed on the first color conversion layer, the second color conversion layer, and the transmission layer. The cover layer may be disposed in an area between a side of the plurality of banks and the at least one of the first color conversion layer and the second color conversion layer, which is thicker than the plurality of banks.

The display device may further include a spacer disposed to overlap the plurality of banks in a plan view.

Two or more of the first color conversion layer, the second color conversion layer, and the transmission layer may have a thickness greater than the thickness of the plurality of banks.

A thickness of the first color conversion layer, a thickness of the second color conversion layer, and a thickness of the transmission layer may be greater than the thickness of the plurality of banks.

The display device may further include a second substrate facing the first substrate, a color filter disposed on the second substrate, and a filling layer disposed between the color filter and the first color conversion layer, the second color conversion layer, and the transmission layer.

The display device may further include a cover layer disposed on the first color conversion layer, the second color conversion layer, and the transmission layer, and a filling layer disposed between the cover layer and the encapsulation layer.

According to an embodiment of the disclosure, a display device may include a first substrate, a transistor disposed on the first substrate, a light emitting device connected to the transistor, an encapsulation layer covering the light emitting device, a plurality of banks disposed to overlap the encapsulation layer in a plan view and partitioning a first emission area, a second emission area, and a third emission area, a first color conversion layer disposed in the first emission area, a second color conversion layer positioned in the second emission area, a transmission layer disposed in the third emission area, and an auxiliary spacer layer disposed to overlap the first color conversion layer or the second color conversion layer in a plan view.

The auxiliary spacer layer and one of the first color conversion layer, the second color conversion layer, and the transmission layer may include a same material.

A height of the auxiliary spacer layer may be in a range of about 1 μm to about 5 μm.

The auxiliary spacer layer may be disposed in contact with at least one of the first color conversion layer, the second color conversion layer, and the transmission layer.

According to an embodiment of the disclosure, a manufacturing method of a display device may include forming a bank having a plurality of openings on a substrate, forming a first color conversion layer and a transmission layer in respective ones of the plurality of openings of the bank, and forming a second color conversion layer having a thickness greater than a thickness of the bank in another one of the plurality of openings of the bank.

The forming of the second color conversion layer may be performed using a photoresist.

The forming of the second color conversion layer may be performed using an inkjet method.

A difference between the thickness of the second color conversion layer and the thickness of the bank may be in a range of about 1 μm to about 5 μm.

According to the embodiments, it is possible to provide a display device with improved light emission efficiency and a manufacturing method therefor.

### BRIEF DESCRIPTION OF THE DRAWINGS

FIG. 1 is a schematic cross-sectional view of a display device according to an embodiment.

FIG. 2 to FIG. 4 are schematic plan views illustrating a stacking order of a blue color filter, a red color filter, and a green color filter.

FIG. 5 is a schematic cross-sectional view of a display device.

FIG. 6 is a schematic cross-sectional view of a display device.

FIG. 7 to FIG. 20 are schematic cross-sectional views of a display device of FIG. 1 according to an embodiment.

FIG. 21 to FIG. 24 are schematic cross-sectional views illustrating a manufacturing process for a display device according to an embodiment.

FIG. 25 and FIG. 26 are schematic cross-sectional views illustrating a manufacturing process for a display device according to an embodiment.

FIG. 27 to FIG. 30 are schematic cross-sectional views illustrating a manufacturing process for a display device according to an embodiment.

### DETAILED DESCRIPTION OF THE EMBODIMENTS

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

To clearly describe the disclosure, parts that are irrelevant to the description are omitted, and like numerals refer to like or similar constituent elements throughout the specification.

Further, since sizes and thicknesses of constituent members shown in the accompanying drawings are arbitrarily given for better understanding and ease of description, the disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Further, throughout the specification, the phrase “in a plan view” means when an object portion is viewed from above, and the phrase “in a cross-sectional view” means when a cross-section taken by vertically cutting an object portion is viewed from the side.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/of” is intended to include any combination of the terms “and” and “or” for the purpose of its meaning and interpretation. For example, “A and/or B” may be understood to mean “A, B, or A and B.” The terms “and” and “of” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, a display device according to an embodiment will be described with reference to the drawings.

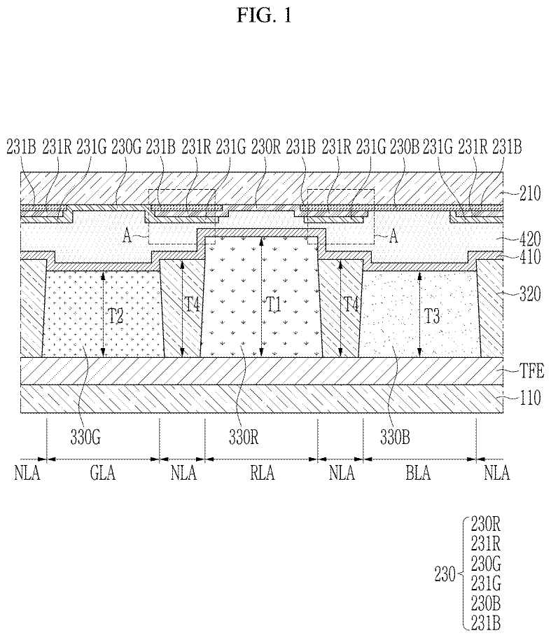

FIG. 1 is a schematic cross-sectional view of a display device according to an embodiment. Referring to FIG. 1, the display device according to the embodiment may include a first substrate 110, a thin film encapsulation layer TFE positioned on the first substrate 110, multiple banks 320, color conversion layers 330R and 330G and a transmission layer 330B disposed between the banks and a cover layer 410 disposed on the color conversion layers 330R and 330G and the transmission layer 330B, a second substrate 210, a color filter 230 positioned at a first side of the second substrate 210, and a filling layer 420 disposed between the color filter 230 and the cover layer 410.

Although not illustrated in FIG. 1, multiple transistors and light emitting devices connected to the transistors may be positioned between the first substrate 110 and the thin film encapsulation layer TFE. A structure between the first substrate 110 and the thin film encapsulation layer TFE may constitute a display panel and may emit light. A stack structure of the display panel will be described separately below. An area between the second substrate 210, the color conversion layers 330R and 330G, and the transmission layer 330B may constitute a color conversion panel, and a description below will focus on a configuration of the color conversion panel.

In the embodiment, light emitted from the display panel may pass through the color conversion layers 330R and 330G or the transmission layer 330B of the color conversion panel, and may be emitted through the color filter 230 and through the second substrate 210.

Hereinafter, a configuration of the color conversion panel will be described in detail. A color filter 230 including a blue color filter 230B, a red color filter 230R and a green color filter 230G may be positioned on the second substrate 210.

Referring to FIG. 1, a blue dummy color filter 231B and the blue color filter 230B may be positioned on a same layer. The blue color filter 230B may be positioned in a blue emission area BLA, and the blue dummy color filter 231B may be positioned in a non-emission area NLA overlapping the banks 320 in a plan view. Although the blue color filter 230B and a blue dummy color filter 231B are illustrated as separate components in FIG. 1, in another embodiment, the blue color filter 230B and a blue dummy color filter 231B may be integral with each other.

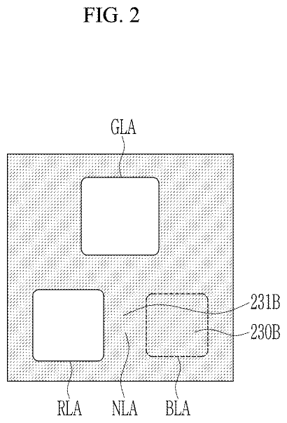

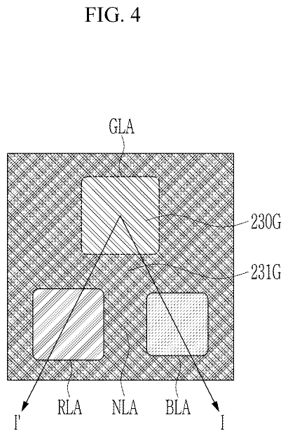

FIG. 2 to FIG. 4 are schematic plan views illustrating a stacking order of the blue color filter 230B, the red color filter 230R, and the green color filter 230G. A cross-section taken along line I-I′ in FIG. 4 may correspond to FIG. 1.

Referring to FIG. 2, the blue color filter may be provided in an entire area except for a green emission area GLA and a red emission area RLA. Among such blue color filters, a blue color filter positioned in the blue emission area BLA may be the blue color filter 230B, and a blue color filter positioned in the non-emission area NLA may be the blue dummy color filter 231B. In FIG. 1, opposite edges of the blue color filter 230B may be non-emission areas NLA overlapping the bank 320, which is the blue dummy color filter 231B.

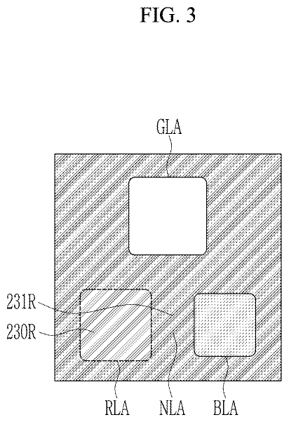

Referring to FIG. 1 and FIG. 3 together, the red color filter 230R and the red dummy color filter 231R may be positioned on the blue color filter 230B and the blue dummy color filter 231B. Referring to FIG. 3, the red color filter may be provided in an entire area except for the green emission area GLA and the blue emission area BLA. Among such red color filters, a red color filter positioned in the red emission area RLA may be the red color filter 230R, and a red color filter positioned in the non-emission area NLA may be the red dummy color filter 231R. In FIG. 1, opposite edges of the red color filter 230R may be non-emission areas NLA overlapping the bank 320, which is the red dummy color filter 231R.

Referring to FIG. 1 and FIG. 4 together, the green color filter 230G and a green dummy color filter 231G may be positioned on the blue color filter 230B, the blue dummy color filter 231i, the red color filter 230R, and the red dummy color filter 231R. Referring to FIG. 4, the green color filter may be positioned in an entire area except for the blue emission area BLA and the red emission area RLA. Among such green color filters, a green color filter positioned in the green emission area GLA may be the green color filter 230G, and a green color filter positioned in the non-emission area NLA may be the green dummy color filter 231G. In FIG. 1, opposite edges of the green color filter 230G may be non-emission areas NLA overlapping the bank 320, which is the green dummy color filter 231G.

Referring to FIG. 1, the blue dummy color filter 231B, the red dummy color filter 231R, and the green dummy color filter 231G may be positioned to overlap in an area overlapping the bank 320 in a plan view. The blue dummy color filter 231B, the red dummy color filter 231R, and the green dummy color filter 231G may overlap to form a color filter overlapping body A. The color filter overlapping body A may function as a light blocking member. For example, the color filter overlapping body A may block light in the non-emission area NLA.

The blue dummy color filter 231B may be positioned closer to the second substrate 210 than the red dummy color filter 231R and the green dummy color filter 231G. A direction in which a user views an image may be toward the second substrate 210, and the blue dummy color filter 231B may be positioned on a surface in which the image is viewed. This is because, compared to green or red, blue has a lowest reflectance for all light and may block light most effectively.

Referring to FIG. 1, the banks 320 may be positioned on the thin film encapsulation layer TFE. The banks 320 may include spaced areas, and the first color conversion layer 330R, the second color conversion layer 330G, and the transmission layer 330B may be disposed in the areas between the banks 320 spaced apart from each other. The first color conversion layer 330R may convert supplied light into red light. Similarly, the second color conversion layer 330G may be disposed in an area overlapping a green light emitting area GLA in a plan view. The second color conversion layer 330G may convert supplied light into green light.

The first color conversion layer 330R and the second color conversion layer 330G may include different semiconductor nanocrystals. The semiconductor nanocrystals may include at least one of a phosphor or quantum dot material that converts incident light into red light or green light.

A diameter of the quantum dots may be, e.g., in a range of about 1 nm to 10 nm.

The quantum dots may be synthesized by a wet chemical process, an organometallic chemical vapor deposition process, a molecular beam epitaxy process, or a process similar thereto.

The wet chemical process is a method of growing a quantum dot particle crystal after mixing an organic solvent and a precursor material. In case that the crystal grows, the organic solvent naturally acts as a dispersant coordinated on the surface of the quantum dot crystal and controls the growth of the crystal, so metal organic chemical vapor deposition (MOCVD) or molecular beam epitaxy (MBE), and the growth of quantum dot particles may be readily controlled through a process that is cheaper than vapor deposition methods such as epitaxy.

The quantum dots may include a Group III-VI semiconductor compound, a Group II-VI semiconductor compound, a Group III-V semiconductor compound, a Group I-III-VI semiconductor compound, a Group IV-VI semiconductor compound, a Group IV element or compound, or a combination thereof.

Examples of Group II-VI semiconductor compounds may include a two-element compound such as CdS, CdSe, CdTe, ZnS, ZnSe, ZnTe, ZnO, HgS, HgSe, HgTe, MgSe, or MgS; a three-element compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; and a four-element compound such as HgZnTeS, CdZnSeS, CdZnSeTe, CdZnSTe, CdHgSeS, CdHgSeTe, CdHgSTe, HgZnSeS, HgZnSeTe, or HgZnSTe, or a combination thereof.

Examples of Group III-V semiconductor compounds may include a two-element compound such as GaN, GaP, GaAs, GaSb, AlN, AlP, AlAs, AlSb, InN, InP, InAs, InSb, and the like; a three-element compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, and the like; and a four-element compound such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, the like, or a combination thereof. Group III-V semiconductor compounds may further include a Group II element. Examples of Group III-V semiconductor compounds further including the Group II element may include InZnP, InGaZnP, InAlZnP, and the like.

Examples of Group III-VI semiconductor compounds may include a two-element compound such as GaS, Ga₂S₃, GaSe, Ga₂Se₃, GaTe, InS, InSe, In₂Se₃, or InTe; a three-element compound such as InGaS₃ or InGaSe₃; or a combination thereof.

Examples of Group I-III-VI semiconductor compounds may include a three-element compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, or AgAlO₂; a four-element compound such as AgInGaS₂ or AgInGaSe₂; or a combination thereof.

Examples of Group IV-VI semiconductor compounds may include a two-element compound such as SnS, SnSe, SnTe, PbS, PbSe, or PbTe; a three-element compound such as SnSeS, SnSeTe, SnSTe, PbSeS, PbSeTe, PbSTe, SnPbS, SnPbSe, or SnPbTe; a four-element compound such as SnPbSSe, SnPbSeTe, or SnPbSTe; or a combination thereof.

The Group IV element or compound may include a single-element compound such as Si or Ge; a two-element compound such as SiC or SiGe; or a combination thereof.

Each element included in a multi-element compound such as a two-element compound, a three-element compound, and a four-element compound may be present in particles at a uniform concentration or a non-uniform concentration. For example, the chemical formula indicates types of elements included in the compound, and element ratios thereof in the compound may be different. For example, AgInGaS₂ may indicate AgInₓGa₁₋ₓS₂ (x being a real number between 0 and 1).

The quantum dots may have a single structure in which a concentration of each element included in the quantum dots is uniform or a double core-shell structure. For example, a material included in the core and a material included in the shell may be different from each other.

The shell of the quantum dot may serve as a passivation layer for maintaining a semiconductor characteristic and/or as a charging layer for applying an electrophoretic characteristic to the quantum dot by preventing chemical denaturation of the core. The shell may be a single layer or a multilayer. An interface between the core and the shell may have a concentration gradient in which a concentration of elements of the shell decreases closer to the center thereof.

For example, the shell of the quantum dot may include a metal or nonmetal oxide, a semiconductor compound, or a combination thereof. Examples of oxides of metals or nonmetals may include a two-element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a three-element compound such as MgAl₂O₄, CoFe₂O₄, NiFe₂O₄, or CoMn₂O₄; or a combination thereof. Examples of the semiconductor compound may include a Group III-VI semiconductor compound, a Group II-VI semiconductor compound, a Group III-V semiconductor compound, a Group III-VI semiconductor compound, a Group I-III-VI semiconductor compound, a Group IV-VI semiconductor compound, or a combination thereof. Examples of the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or a combination thereof.

Each element included in a multi-element compound such as a two-element compound or a three-element compound may be present in particles at a uniform concentration or a non-uniform concentration. For example, the chemical formula indicates types of elements included in the compound, and element ratios thereof in the compound may be different.

The quantum dots may have a full width at half maximum (FWHM) of the light-emitting wavelength spectrum that is equal to or less than about 45 nm. For example, the quantum dots may have a full width at half maximum (FWHM) of the light-emitting wavelength spectrum that is equal to or less than about 40 nm. For example, the quantum dots may have a full width at half maximum (FWHM) of the light-emitting wavelength spectrum that is equal to or less than about 30 nm. In this range, color purity or color reproducibility may be improved. Since light emitted through the quantum dot is emitted in all directions, a viewing angle of light may be improved.

A shape of the quantum dots may be in the form of spherical, pyramidal, multi-armed, cubic nanoparticles, nanotubes, nanowires, nanofibers, nanoplatelet particles, or the like.

An energy band gap may be controlled by adjusting the size of the quantum dots or an element ratio in a quantum dot compound, and thus light of various wavelengths may be obtained from a quantum dot emission layer. Accordingly, a light emitting device emitting light of various wavelengths may be implemented by using quantum dots as described above (using quantum dots of different sizes or having different element ratios in a quantum dot compound). Specifically, control of the size of the quantum dots or the element ratios in the quantum dot compound may be selected to emit red, green and/or blue light. The quantum dots may emit white light by combining light of various colors.

The transmission layer 330B may include scatterers. The scatterers may include at least one of SiO₂, BaSO₄, Al₂O₃, ZnO, ZrO₂, and TiO₂. The transmission layer 330B may include a polymer resin and a scatterer included in the polymer resin. For example, the transmission layer 330B may include TiO₂, but the disclosure is not limited thereto. The transmission layer 330B may transmit light incident from the display panel.

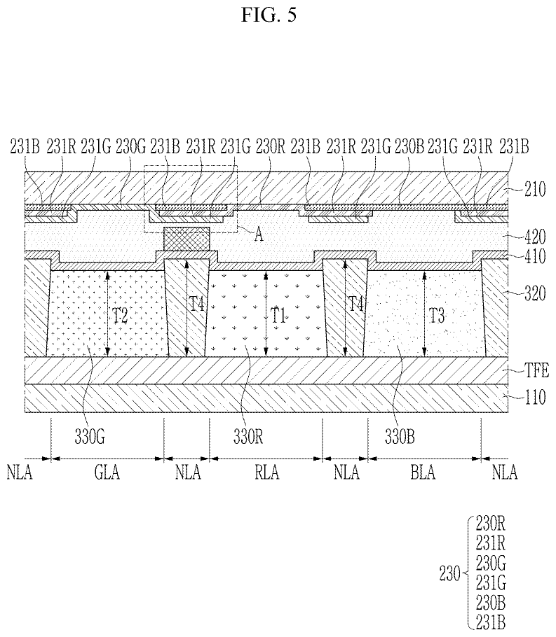

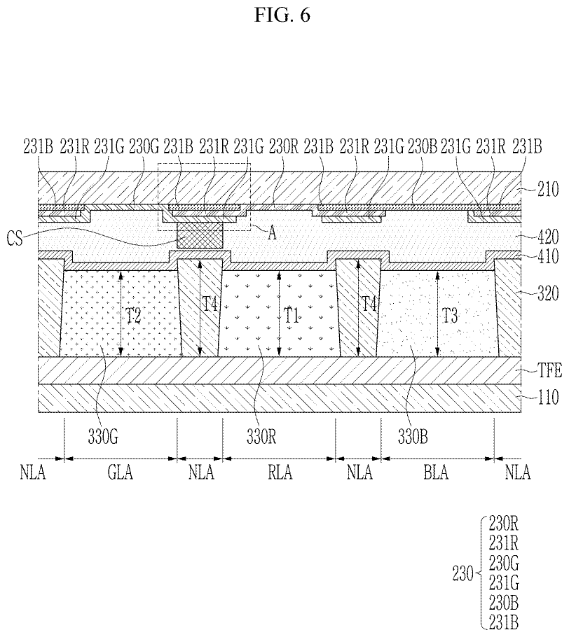

Referring to FIG. 1, in the embodiment, a thickness T1 of the first color conversion layer 330R may be greater than a thickness T2 of the second color conversion layer 330G and a thickness T3 of the transmission layer 330B. As illustrated in FIG. 1, the thickness T1 of the first color conversion layer 330R may be greater than a thickness T4 of the bank 320. For example, in the display device according to the embodiment, the first color conversion layer 330R may be formed to protrude beyond the bank 320. The first color conversion layer 330R may function like a column spacer, and a separate column spacer formation process may be omitted. Therefore, the manufacturing process may be simplified. For example, a general display panel includes a column spacer CS positioned on the bank 320 as illustrated in FIG. 5, or a column spacer CS positioned on a color filter overlap body A as illustrated in FIG. 6. This is to maintain a uniform cell gap. Accordingly, a separate process is required to form this column spacer CS. As illustrated in FIG. 5 and FIG. 6, the filling layer 420 is positioned between the color filter 230, the color conversion layers 330R and 330G, and the transmission layer 330B, and due to this filling layer 420, light emission efficiency of the color conversion layers 330R and 330G and the transmission layer 330B may be reduced.

However, in the display device according to the embodiment, the first color conversion layer 330R may be formed to be higher than the bank 320 to function as a column spacer. Accordingly, a separate process of forming a column spacer may be omitted. As illustrated in FIG. 1, as a thickness of the first color conversion layer 330R increases, a thickness of the overlapping filling layer 420 becomes thinner than that in FIG. 5 and FIG. 6, so a decrease in light emission efficiency caused by the filling layer 420 may be minimized. As the thickness of the first color conversion layer 330R increases, a region where color conversion occurs increases, thereby maximizing light emission efficiency.

The thickness T1 of the first color conversion layer 330R may be greater than the thickness T4 of the bank 320 by 1 μm to 5 μm. In case that a thickness difference is smaller than 1 μm, the first color conversion layer 330R may not function as a column spacer, and in case that the thickness difference is greater than 5 μm, a thickness of the filling layer 420 may become thick, which may cause a problem of reduced light efficiency.

The cover layer 410 may be disposed on the color conversion layers 330R and 330G and the transmission layer 330B. The cover layer 410 may include an inorganic material, and may cap the color conversion layers 330R and 330G and the transmission layer 330B. The cover layer 410 may include silicon oxide or silicon nitride. The filling layer 420 may be disposed between the cover layer 410 and the color filter 230. The filling layer 420 may include an organic material—e.g., polyimide.

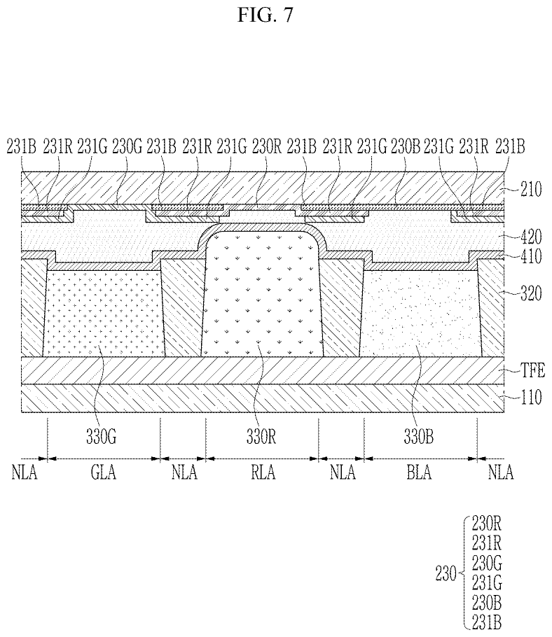

In FIG. 1, an upper end of the first color conversion layer 330R is illustrated in a quadrangular shape, but the shape of the first color conversion layer 330R is not limited thereto. FIG. 7 is a schematic cross-sectional view of a display device of FIG. 1 according to an embodiment. Referring to FIG. 7, the display device according to the embodiment and the embodiment of FIG. 1 may be same except that the upper end of the first color conversion layer 330R is curved. A detailed description of same constituent elements will be omitted.

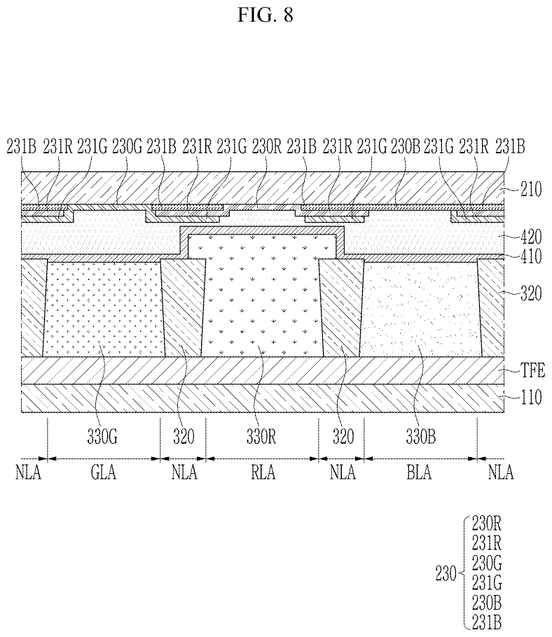

In FIG. 1 and FIG. 7, the first color conversion layer 330R is illustrated in a shape that does not overlap the bank 320, but the disclosure is not limited thereto, and the first color conversion layer 330R may be disposed overlapping the bank 320 in another embodiments. FIG. 8 is a schematic cross-sectional view of a display device of FIG. 1 according to an embodiment. Referring to FIG. 8, the display device according to the embodiment and the embodiment of FIG. 1 may be same except that a portion of the first color conversion layer 330R is disposed on the bank 320 to overlap the bank 320 in a plan view. A detailed description of same constituent elements will be omitted.

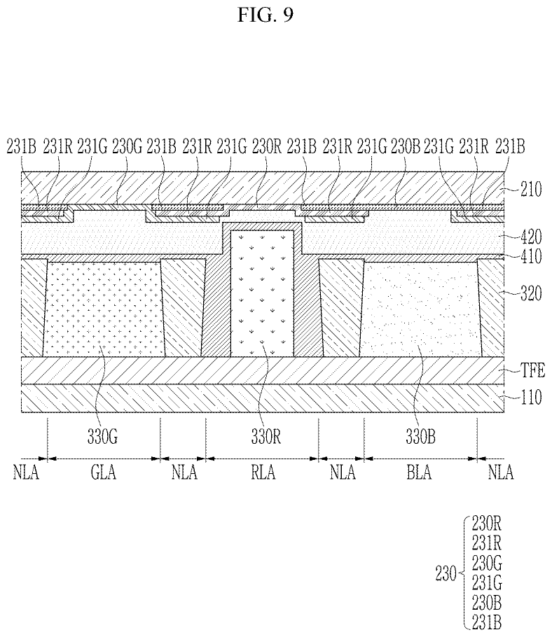

In the previous embodiment, the bank 320 and the first color conversion layer 330R are shown to have a configuration in which they are not spaced apart, but a width of the first color conversion layer 330R may be smaller than a width of the bank 320. FIG. 9 is a schematic cross-sectional view of a display device of FIG. 1 according to an embodiment. Referring to FIG. 9, a side surface of the first color conversion layer 330R and a side surface of the bank 320 may be spaced apart, and the cover layer 410 may be disposed the bank 320 and the first color conversion layer 330R. In this structure, light converted in the first color conversion layer 330R may be scattered by the cover layer 410 without being absorbed by the bank 320, thereby improving luminous efficiency. In FIG. 9, the first color conversion layer 330R may be thicker than the bank 320, and the first color conversion layer 330R may protrude to function as a spacer. Since other components are the same as in FIG. 1, detailed descriptions of the same components will be omitted.

In the previous embodiment, a configuration in which the first color conversion layer 330R is formed in one process has been described, but according to another embodiment, a spacer color conversion layer 330SR may be disposed on the first color conversion layer 330R in a separate process.

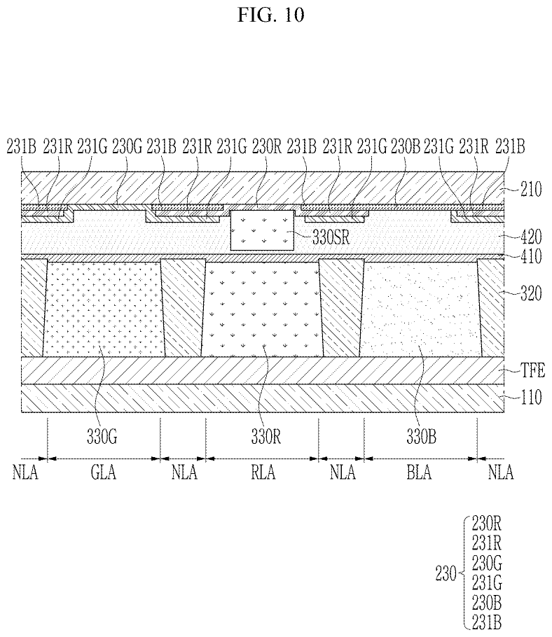

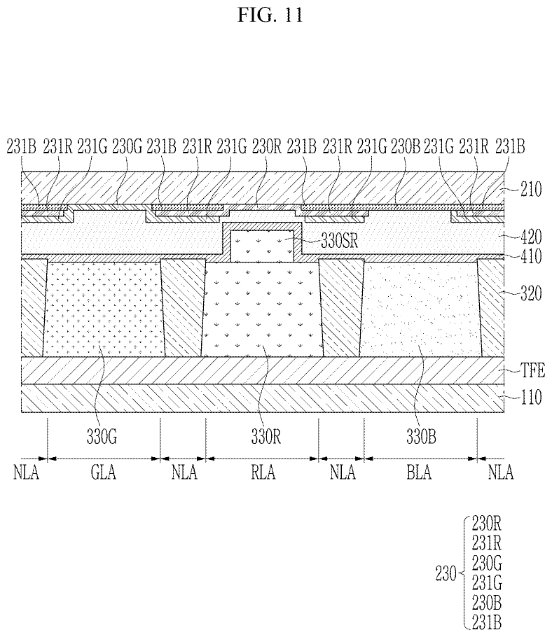

FIG. 10 and FIG. 11 are each schematic cross-sectional view of a display device of FIG. 1 according to an embodiment. The embodiment of FIG. 10 and FIG. 11 and the embodiment of FIG. 1 may be same except that a spacer color conversion layer 330SR is disposed separately from the first color conversion layer 330R. A detailed description of same constituent elements will be omitted. FIG. 10 schematically illustrates an embodiment in which the spacer color conversion layer 330SR is disposed on the color filter 230, and FIG. 11 schematically illustrates an embodiment in which the spacer color conversion layer 330SR is disposed on the first color conversion layer 330R.

In the embodiments of FIG. 10 and FIG. 11, the spacer color conversion layer 330SR and the first color conversion layer 330R may include a same material. In the embodiments of FIG. 10 and FIG. 11, an area occupied by the filling layer 420 may be reduced by the spacer color conversion layer 330SR, thereby minimizing a reduction in light emission efficiency caused by the filling layer 420. Color conversion may occur in the spacer color conversion layer 330SR, thereby maximizing light emission efficiency.

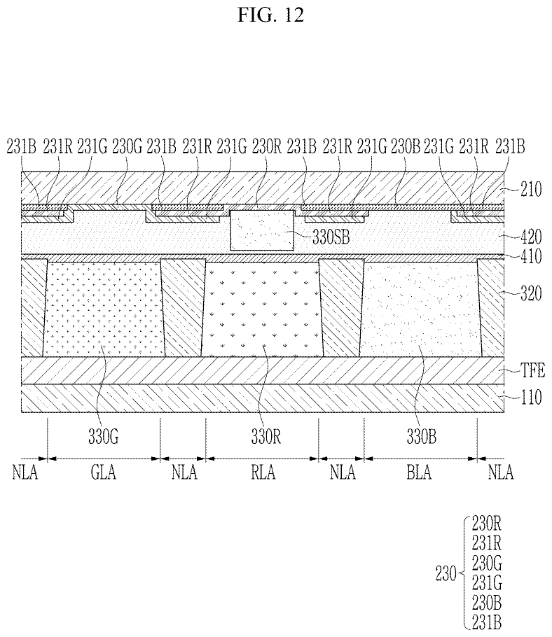

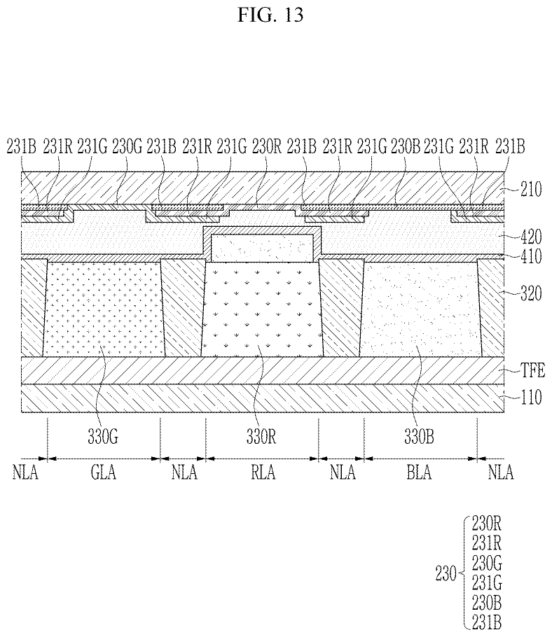

FIG. 12 to FIG. 13 are each cross-sectional view of a display device of FIG. 11 and FIG. 12 according to an embodiment. The embodiment of FIG. 12 and FIG. 13 and the embodiment of FIG. 11 and FIG. 12 may be same except that a spacer scattering layer 330SB and the transmission layer 330B may include a same material. A detailed description of the same constituent elements will be omitted. FIG. 12 schematically illustrates an embodiment in which the spacer scattering layer 330SB is disposed on the color filter 230, and FIG. 13 schematically illustrates an embodiment in which the spacer scattering layer 330SB is disposed on the first color conversion layer 330R.

In the embodiments of FIG. 12 and FIG. 13, an area occupied by the filling layer 420 may be reduced by the spacer scattering layer 330SB, thereby minimizing a reduction in light emission efficiency caused by the filling layer 420. Light emitted from the first color conversion layer 330R may be scattered by the spacer scattering layer 330SB, thereby improving light emission efficiency.

The spacer color conversion layer 330SR and the spacer scattering layer 330SB may each function as an auxiliary spacer, and the thickness of the auxiliary spacer may be in a range of about 1 μm to about 5 μm.

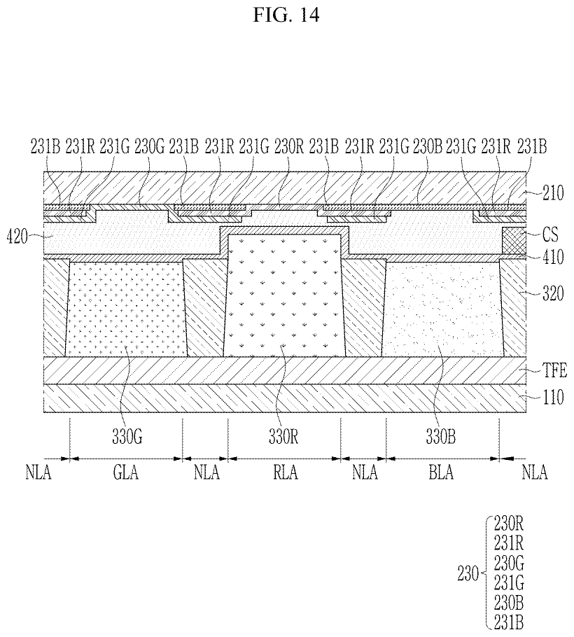

In the previous embodiment, a configuration that does not include a separate spacer was illustrated, but the disclosure is not limited thereto, and a display device may include a spacer. FIG. 14 is a schematic cross-sectional view of a display device of FIG. 1 according to an embodiment. Referring to FIG. 14, the display device according to the embodiment and the embodiment of FIG. 1 may be same except that the spacer CS is further included. A detailed description of the same constituent elements will be omitted.

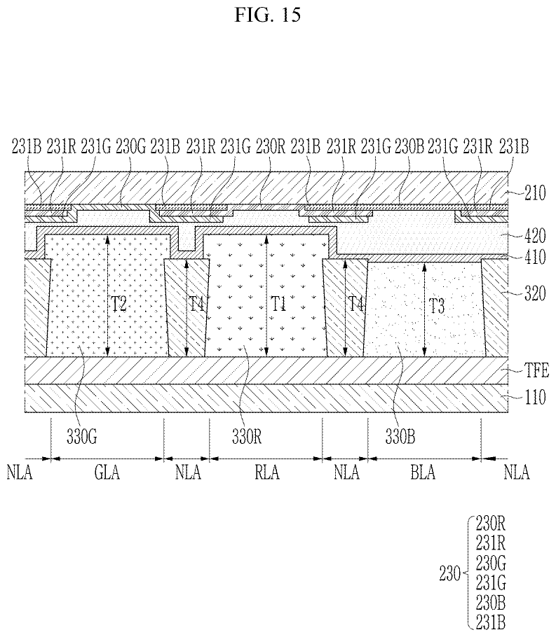

In the previous embodiment, only the first color conversion layer 330R is illustrated to protrude beyond the bank 320, but the second color conversion layer 330G and the transmission layer 330B may also protrude beyond the bank 320. The embodiment of FIG. 15 and the embodiment of FIG. 1 may be same except that the second color conversion layer 330G also protrudes beyond the bank 320. A detailed description of the same constituent elements will be omitted.

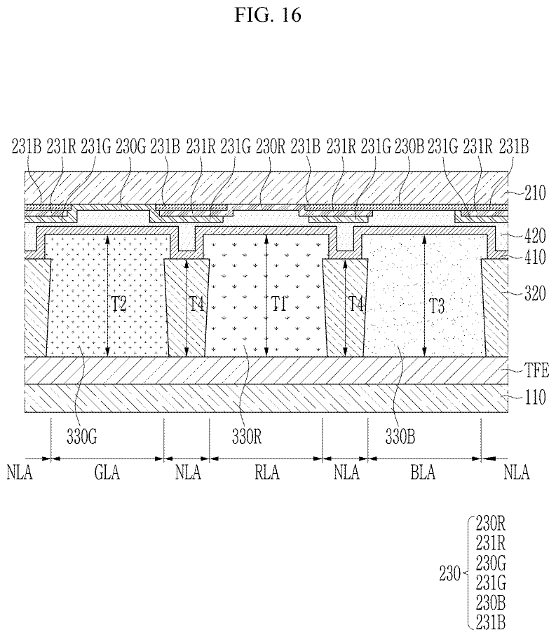

The embodiment of FIG. 16 and the embodiment of FIG. 1 may be same except that both the second color conversion layer 330G and the transmission layer 330B protrude beyond the bank 320. A detailed description of the same constituent elements will be omitted.

As such, as in the embodiments of FIG. 15 and FIG. 16, in case that the second color conversion layer 330G or the transmission layer 330B protrudes in addition to the first color conversion layer 330R, a cell gap may be better maintained and the area occupied by the filling layer 420 may be reduced, and thus a decrease in light emission efficiency caused by the filling layer 420 may be minimized.

In the previous embodiment, the embodiment in which the first color conversion layer 330R protrudes from the bank 320 was described, but the disclosure is not limited thereto, and the second color conversion layer 330G may protrude from the bank 320. The transmission layer 330B may protrude from the bank 320.

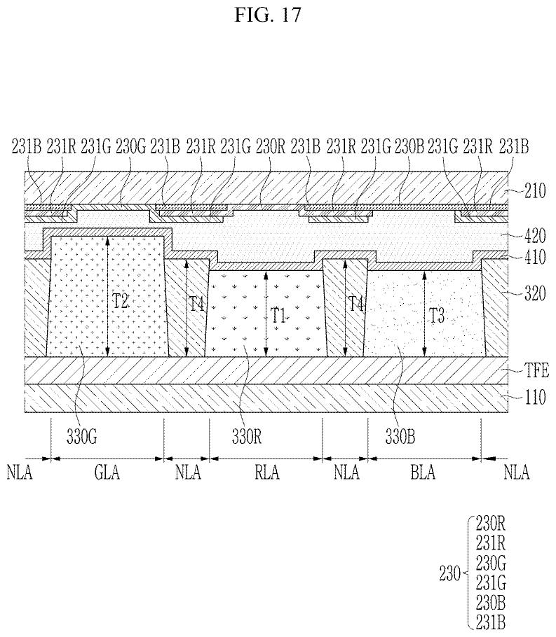

The embodiment of FIG. 17 and the embodiment of FIG. 1 may be same except that the second color conversion layer 330G protrudes beyond the bank 320 instead of the first color conversion layer 330R. A detailed description of the same constituent elements will be omitted. The embodiment of FIG. 17 may be modified to the embodiments of FIG. 7 to FIG. 16.

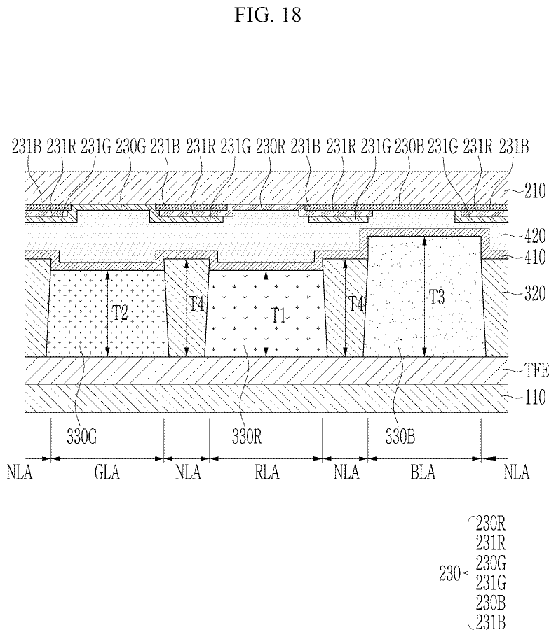

The embodiment of FIG. 18 and the embodiment of FIG. 1 may be same except that the transmission layer 330B protrudes beyond the bank 320 instead of the first color conversion layer 330R. A detailed description of the same constituent elements will be omitted. The embodiment of FIG. 18 may be modified to the embodiments of FIG. 7 to FIG. 16.

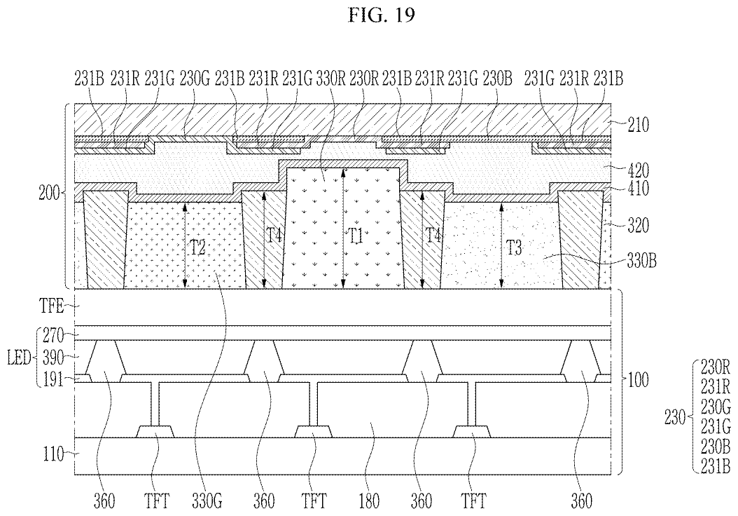

FIG. 19 is a schematic cross-sectional view of a display device according to an embodiment in more detail compared to FIG. 1. In FIG. 19, the color conversion panel 200 is the same as described above, and thus a description thereof will focus on a structure of the display panel 100.

The display panel 100 may include a first substrate 110, multiple transistors TFT positioned on the first substrate 110, and an insulating layer 180. A first electrode 191 and a partition wall 360 may be positioned on the insulating layer 180, and the first electrode 191 may be positioned in an opening of the partition wall 360 and may be connected to the transistor TFT. Although not specifically illustrated, the transistor TFT may include a semiconductor layer, source and drain electrodes connected to the semiconductor layer, and a gate electrode insulated from the semiconductor layer. A second electrode 270 may be positioned on the partition wall 360, and a light emitting device layer 390 may be positioned between the first electrode 191 and the second electrode 270. The first electrode 191, the second electrode 270, and the light emitting device layer 390 may be collectively referred to as a light emitting device LED. The light emitting devices LED may emit light of different colors, or may emit light of the same color. For example, the light emitting devices LED may emit red light, green light, and blue light. For example, the light emitting devices LED may emit blue light and green light. The light emitting devices LED may have structures in which light emitting devices emitting different colors are stacked each other. For example, in the light emitting devices LED, an emission layer emitting blue light and a light emitting layer emitting green light may be stacked each other. For example, emission layers emitting blue light, green light, and red light may be stacked each other. The partition wall 360 may include a black material to prevent color mixing between adjacent light emitting devices LED.

In FIG. 19, an encapsulation layer TFE may be positioned on the light emitting device LED of the display panel 100. The encapsulation layer TFE may have a multi-layered structure in which an organic layer and an inorganic layer are alternately stacked each other. Among multi-layered encapsulation layers TFE, a layer that is positioned farthest from the first substrate 110 may include SiON. A description of the color conversion panel 200 is the same as in FIG. 1, and thus will be omitted.

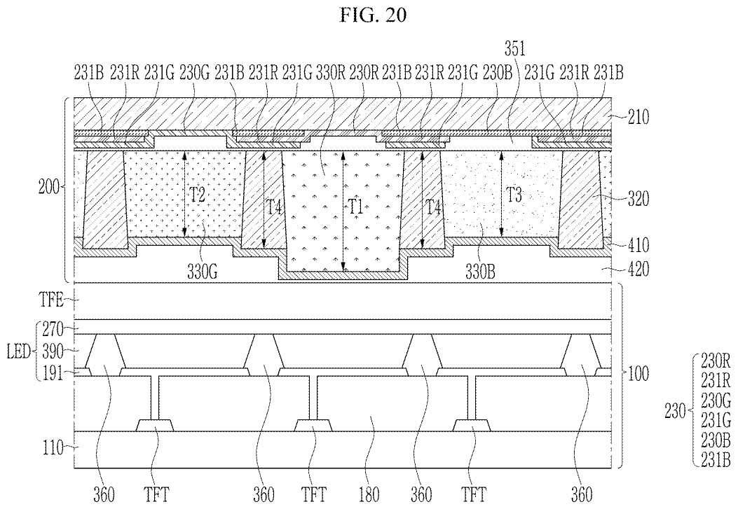

FIG. 20 is a schematic cross-sectional view of a display device of FIG. 19 according to an embodiment. In the previous embodiment, a configuration in which the color conversion layers 330R and 330G and the transmission layer 330B are disposed on the encapsulation layer TFE was disclosed, but according to another embodiment, the color conversion layers 330R and 330G and the transmission layer 330B may be disposed on the color filter 230. In the previous embodiment, the first color conversion layer 330R protrudes in a direction toward the second substrate 210, but the disclosure is not limited thereto, and in an embodiment, the first color conversion layer 330R may protrude in a direction toward the first substrate 110. Referring to FIG. 20, a low refractive index layer 351 may be positioned on the color filter 230. The low refractive index layer 351 may have a refractive index of less than or equal to about 1.2. The low refractive index layer 351 may be a mixture of an organic material and an inorganic material. However, the above refractive index and material are only examples, and the low refractive index layer 351 is not limited thereto. The bank 320 may be positioned on the low refractive layer 351, and the color conversion layers 330R and 330G and the transmission layer 330B may be positioned between the banks 320. The thickness T1 of the first color conversion layer 330R may be greater than the thickness T4 of the bank 320. For example, as illustrated in FIG. 20, the first color conversion layer 330R may protrude in a direction toward the first substrate 110. The cover layer 410 and the filling layer 420 may be disposed on the color conversion layers 330R and 330G and the transmission layer 330B. Descriptions of the cover layer 410 and the filling layer 420 are the same as those described above and will therefore be omitted. A description of the display panel 100 is the same as that in FIG. 19.

Hereinafter, a manufacturing method for a display device according to an embodiment of the disclosure will be described in detail with reference to the drawings.

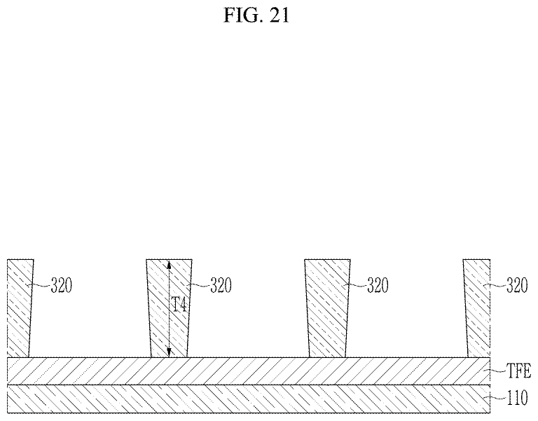

FIG. 21 to FIG. 24 are schematic cross-sectional views illustrating a manufacturing process for a display device according to an embodiment. Referring to FIG. 21, the bank 320 may positioned on the display panel. In FIG. 21, the display panel is schematically illustrated as including the first substrate 110 and the encapsulation layer TFE.

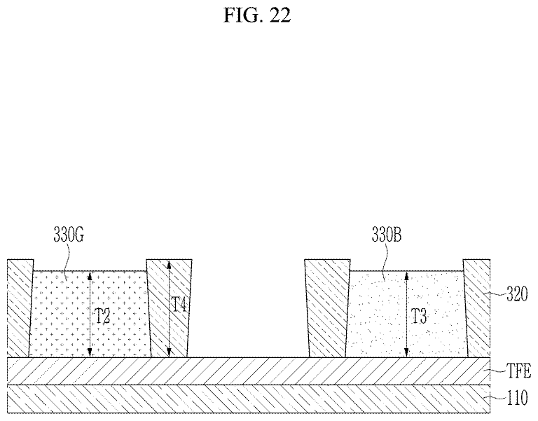

Referring to FIG. 22, the second color conversion layer 330G and the transmission layer 330B may be formed in a space between the banks 320. The second color conversion layer 330G and the transmission layer 330B may be formed using an inkjet method or a photoresist method.

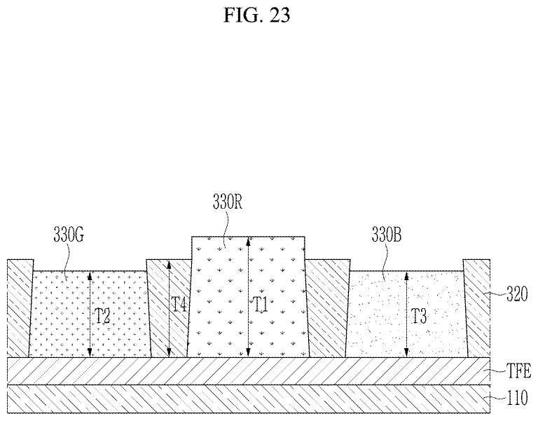

Referring to FIG. 23, the first color conversion layer 330R may be formed. The thickness T1 of the first color conversion layer 330R may be greater than the thickness T4 of the bank 320, the thickness T2 of the second color conversion layer 330G, and the thickness T3 of the transmission layer 330B. The first color conversion layer 330R may be formed through a photoresist process. Accordingly, the protruding first color conversion layer 330R may be formed as illustrated in FIG. 23.

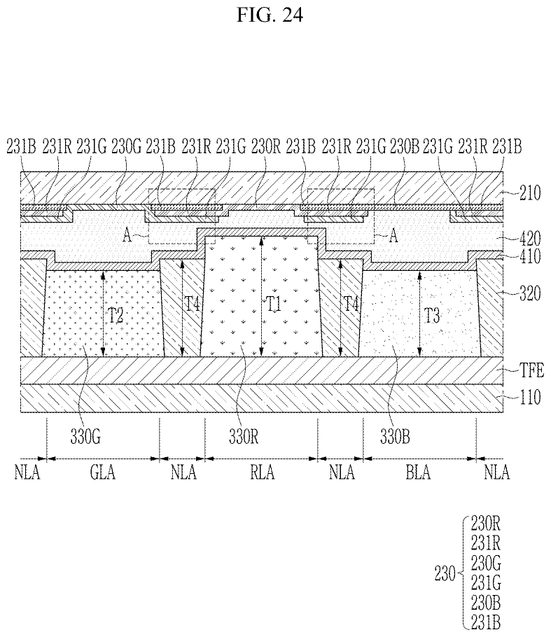

Referring to FIG. 24, the cover layer 410 may be disposed on the first color conversion layer 330R, the second color conversion layer 330G, and the transmission layer 330B. The cover layer 410 may be formed by chemical vapor deposition (CVD). Thereafter, the second substrate 210 on which the color filter 230 is formed may be bonded, and the filling layer 420 may be formed the first substrate 110 and the second substrate 210 to manufacture a display device.

As described above, in the embodiments of FIG. 21 to FIG. 24, the first color conversion layer 330R may be formed using a photoresist method.

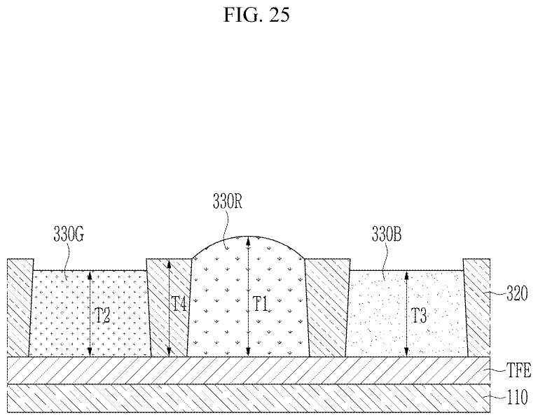

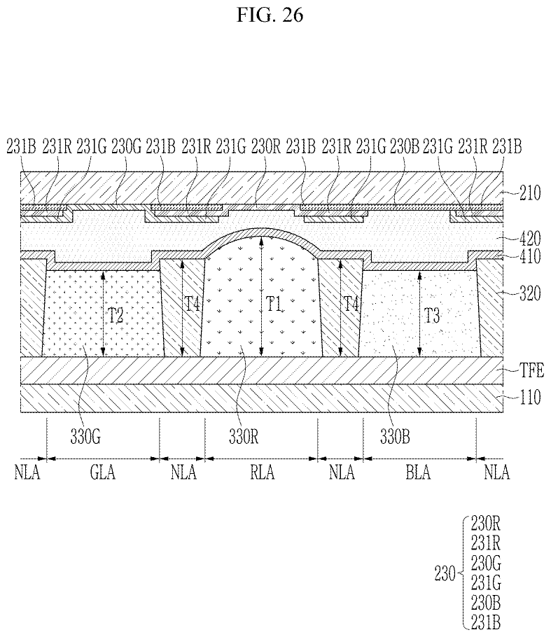

In another embodiment, the first color conversion layer 330R may be formed by an inkjet method. FIG. 25 and FIG. 26 are schematic views illustrating a manufacturing process for a display device according to an embodiment. The bank 320, the second color conversion layer 330G, and the transmission layer 330B may be formed through the processes of FIG. 21 and FIG. 22. Referring to FIG. 25, the first color conversion 330R may be formed. The thickness T1 of the first color conversion layer 330R may be greater than the thickness T4 of the bank 320, the thickness T2 of the second color conversion layer 330G, and the thickness T3 of the transmission layer 330B. In the case of forming the first color conversion layer 330R using an inkjet method, a round shape may be formed through a liquid-repellent property and surface tension of an upper portion of the bank 320 by spraying a large amount of a material of the first color conversion layer 330R. Accordingly, the thickness T1 of the first color conversion layer 330R may be greater than the thickness T4 of the bank 320 without any additional process. Referring to FIG. 26, a display device may be manufactured by forming the cover layer 410 on the first color conversion layer 330R, the second color conversion layer 330G, and the transmission layer 330B, bonding the second substrate 210 on which the color filter 230 is formed, and forming the filling layer 420 between the first substrate 100 and the second substrate 210. For example, in the embodiments of FIG. 25, and FIG. 26, the first color conversion layer 230R may be formed using an inkjet method.

In the previous embodiment, the color conversion layers 330R and 330G and the transmission layer 330B were formed after forming the bank 320, but the bank 320 may be formed after forming the color conversion layers 330R and 330G, and the transmission layer 330B.

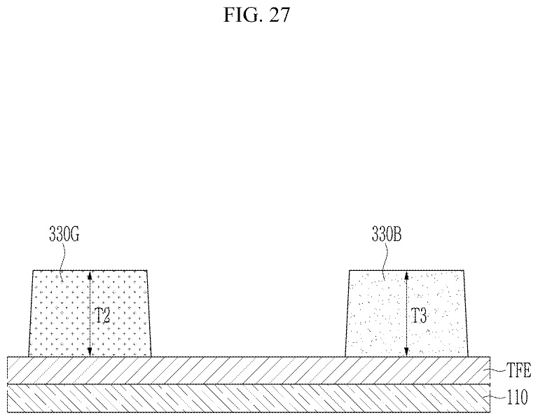

FIG. 27 to FIG. 30 are schematic cross-sectional views illustrating a manufacturing process for a display device according to an embodiment. Referring to FIG. 27, the second color conversion layer 330G and the transmission layer 330B may be disposed on the display panel including the first substrate 110 and the encapsulation layer TFE. The second color conversion layer 330G and the transmission layer 330B may be formed using a photoresist method.

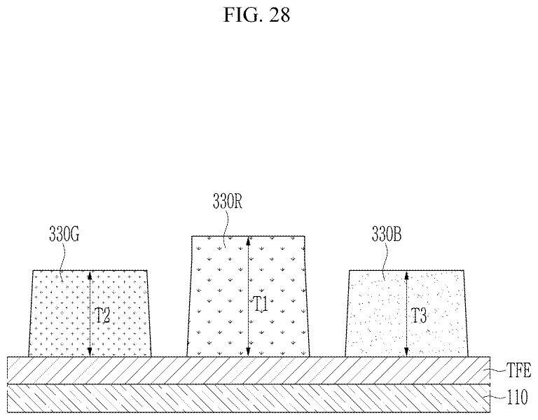

Referring to FIG. 28, the first color conversion layer 330R may be formed. The thickness T1 of the first color conversion layer 330R may be greater than the thickness T2 of the second color conversion layer 330G and the thickness T3 of the transmission layer 330B. The first color conversion layer 330R may be formed through a photoresist process. Accordingly, the protruding first color conversion layer 330R may be formed as illustrated in FIG. 28. The first color conversion layer 330R, the second color conversion layer 330G, and the transmission layer 330B may be formed to be spaced apart from each other.

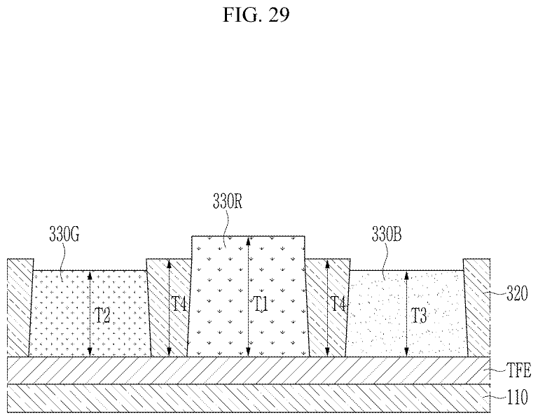

Referring to FIG. 29, the bank 320 may be formed between the first color conversion layer 330R, the second color conversion layer 330G, and the transmission layer 330B. The thickness T4 of the bank 320 may be smaller than the thickness T1 of the first color conversion layer 330R.

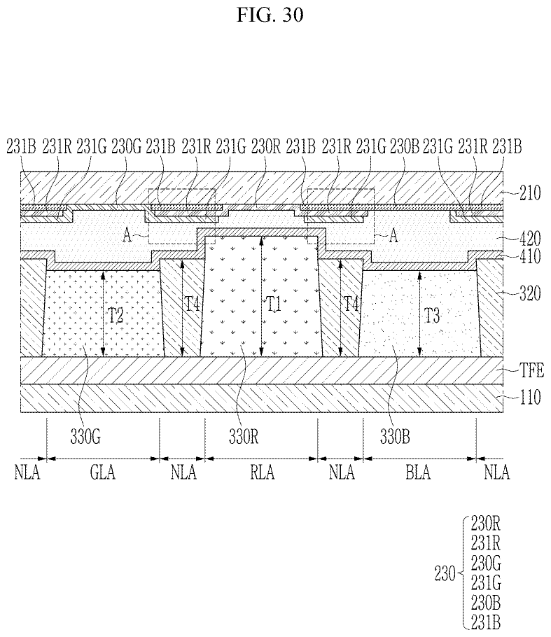

Referring to FIG. 30, a display device may be manufactured by forming the cover layer 410 on the first color conversion layer 330R, the second color conversion layer 330G, and the transmission layer 330B, bonding the second substrate 210 on which the color filter 230 is formed, and forming the filling layer 420 between the first substrate 110 and the second substrate 210.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first substrate;
a transistor disposed on the first substrate;
a light emitting device connected to the transistor;
an encapsulation layer covering the light emitting device;
a plurality of banks disposed to overlap the encapsulation layer in a plan view and partitioning a first emission area, a second emission area, and a third emission area;
a first color conversion layer disposed in the first emission area;
a second color conversion layer disposed in the second emission area; and
a transmission layer disposed in the third emission area,
wherein a thickness of at least one of the first color conversion layer and the second color conversion layer is greater than a thickness of the plurality of banks.

2. The display device of claim 1, wherein a difference between the thickness of the at least one of the first color conversion layer and the second color conversion layer and the thickness of the plurality of banks is in a range of about 1 μm to about 5 μm.

3. The display device of claim 1, wherein an upper surface of the at least one of the first color conversion layer and the second color conversion layer, which is thicker than the thickness of the plurality of banks, is flat.

4. The display device of claim 1, wherein an upper surface of the at least one of the first color conversion layer and the second color conversion layer, which is thicker than the thickness of the plurality of banks, is curved.

5. The display device of claim 1, wherein
a portion of the at least one of the first color conversion layer and the second color conversion layer, which is thicker than the thickness of the plurality of banks, is disposed to overlap the plurality of banks in a plan view.

6. The display device of claim 1, wherein a side surface of the at least one of the first color conversion layer and the second color conversion layer, which is thicker than the thickness of the plurality of banks, is spaced apart from the plurality of banks.

7. The display device of claim 6, further comprising:
a cover layer disposed on the first color conversion layer, the second color conversion layer, and the transmission layer,
wherein the cover layer is disposed in an area between a side of the plurality of banks and the at least one of the first color conversion layer and the second color conversion layer, which is thicker than the plurality of banks.

8. The display device of claim 1, further comprising:
a spacer disposed to overlap the plurality of banks in a plan view.

9. The display device of claim 1, wherein two or more of the first color conversion layer, the second color conversion layer, and the transmission layer have a thickness greater than the thickness of the plurality of banks.

10. The display device of claim 1, wherein a thickness of the first color conversion layer, a thickness of the second color conversion layer, and a thickness of the transmission layer is greater than the thickness of the plurality of banks.

11. The display device of claim 1, further comprising:
a second substrate facing the first substrate;
a color filter disposed on the second substrate; and
a filling layer disposed between the color filter and the first color conversion layer, the second color conversion layer, and the transmission layer.

12. The display device of claim 1, further comprising:
a cover layer disposed on the first color conversion layer, the second color conversion layer, and the transmission layer; and
a filling layer disposed between the cover layer and the encapsulation layer.

13. A display device comprising:
a first substrate;
a transistor disposed on the first substrate;
a light emitting device connected to the transistor;
an encapsulation layer covering the light emitting device;
a plurality of banks disposed to overlap the encapsulation layer in a plan view and partitioning a first emission area, a second emission area, and a third emission area;
a first color conversion layer disposed in the first emission area;
a second color conversion layer disposed in the second emission area;
a transmission layer disposed in the third emission area; and
an auxiliary spacer layer disposed to overlap the first color conversion layer or the second color conversion layer in a plan view.

14. The display device of claim 13, wherein the auxiliary spacer layer and one of the first color conversion layer, the second color conversion layer, and the transmission layer include a same material.

15. The display device of claim 13, wherein a height of the auxiliary spacer layer is in a range of about 1 μm to about 5 μm.

16. The display device of claim 13, wherein the auxiliary spacer layer is disposed in contact with at least one of the first color conversion layer, the second color conversion layer, and the transmission layer.

17. A manufacturing method for a display device, comprising:
forming a bank having a plurality of openings on a substrate;
forming a first color conversion layer and a transmission layer in respective ones of the plurality of openings of the bank; and
forming a second color conversion layer having a thickness greater than a thickness of the bank in another one of the plurality of openings of the bank.

18. The manufacturing method of claim 17, wherein the forming of the second color conversion layer is performed using a photoresist method.

19. The manufacturing method of claim 17, wherein the forming of the second color conversion layer is performed using an inkjet method.

20. The manufacturing method of claim 17, wherein a difference between the thickness of the second color conversion layer and the thickness of the bank is in a range of about 1 μm to about 5 μm.
